(19) United States
(12) Patent Application Publication
(10) Pub. No.: US 2002/0134579 A1
(43) Pub. Date: Sep. 26, 2002

(54) Method and device for avoiding electrostatic discharge of an electronic device by using electroconductive sheet

(75) Inventor: Kenji Saito, Sagamihara-shi (JP)

Correspondence Address: FRISHAUF, HOLTZ, GOODMAN & CHICK, PC, 767 THIRD AVENUE, 25TH FLOOR, NEW YORK, NY, 10017-2023, US

(73) Assignee: Mitsumi Electric Co. Ltd., Tokyo (JP)

(21) Appl. No.: 10/104,801

(22) Filed: Mar. 22, 2002

(30) Foreign Application Priority Data
Mar. 23, 2001 (JP) 85239/2001

(51) Int. Cl. H05K 1/03

(52) U.S. Cl. 174/255

(57) ABSTRACT

An electroconductive sheet is stuck on electrodes of an electronic device so as to electrically connect the electrodes with each other. Next, the electrodes are inserted into a corresponding connector. Finally, the electroconductive sheet is peeled from the electrodes.

### BACKGROUND OF THE INVENTION

This invention relates to protection of electronic devices from electrostatic discharge. This invention is particularly available for protecting magnetoresistive devices connected with FPCs (Flexible Printed Circuit) from electrostatic discharge. Magnetoresistive devices are typically installed on magnetic heads of magnetic recording/reproducing devices, which is for example liner tape storage systems such as DLT (Digital Liner Tape) and LTO (Liner Tape Open).

Some electronic devices are easily damaged by electrostatic discharge. Electrostatic discharge of electronic devices in particular occurs while they are transported or installed to other devices. A magnetoresistive device is typical one of the electronic devices. A magnetoresistive device is included in a magnetic recording/reproducing device as its magnetic head and is easily damaged by electrostatic discharge. Turning to. FIG. 1, a magnetic head 40 includes a magnetoresistive device 41 and a FPC 42. Although terminals of the magnetoresistive device 41 are connected with one end of the FPC 42, electrodes 43 on the other end of the FPC 42 is exposed. Therefore, the magnetoresistive device 41 may be damaged by electrostatic discharge.

In order to prevent electrostatic discharge, the FPC 42 has conventionally been held with a metallic clip at the electrodes 43. According to this, as shown in FIG. 2, a metallic clip 44 clips the FPC 42 at the electrodes 43, so as to electrically connect the electrodes 43 with each other and keep the magnetoresistive device 41 in electrically closed state. The magnetic head 40 is transported to a destination with the magnetoresistive device 41 clipped. When the magnetic head has arrived at the destination and is about to be installed to a connector of another device (not shown), the clip 44 is removed from the magnetoresistive device 41 and immediately inserted into the connector.

According to the conventional method, the magnetoresistive device 41 is protected from electrostatic discharge during transportation. As a result, the conventional technique can lower possibility that electrostatic discharge damages the magnetoresistive device 41.

On the other hand, the conventional method also includes defenseless steps against electrostatic discharge. Before inserting the magnetoresistive device 41 into the connector, first (1) the metallic clip 44 is removed from the electrodes 43, and then (2) the electrodes 43 is inserted into the connector. It is noted that since the electrodes 43 is electrically opened between (1) and (2), the magnetoresistive device 41 is in defenseless state against electrostatic discharge.

According to the conventional method, it is required to pinch the lever ends of the metallic clip 44 by fingers so as to remove the clip 44 from the magnetoresistive device 41. This pinching action requires some working space for handling the lever ends. It may be difficult or impossible inside a destination device or apparatus to which the magnetic head 40 is installed, because the apparatus is often made small size without any space sufficient to enable the pinching action therein. Therefore, the metallic clip 44 must often be removed outside the apparatus and the step is thus performed before assembling the magnetoresistive device 41 into the apparatus. In this case, however, defenseless time period against electrostatic discharge should be longer.

Furthermore, the conventional method requires the metallic clip 44, which is suitable for the dimension and shape of the electrodes 43. The dimension and shape of the electrodes 43 restrict those of the metallic clip 44. If metallic clips of a single type are provided for the metallic clips 44, then the dimension and shape of the electrodes 43 is restricted. On the other hand, if metallic clips of different types are provided for various kinds of electrodes used as the electrodes 43, preparation of metallic clips of various different types causes high cost of production.

### SUMMARY OF THE INVENTION

The present invention takes the above-mentioned circumstance into consideration. It is an object of the present invention to provide techniques foravoiding the defenseless time against electrostatic discharge of an electronic device while installation of the electronic device to another device.

It can be another object of the present invention to provide techniques for installing an electronic device to another device without both electrostatic discharge and troublesome jobs.

It can be another object of the present invention to provide techniques flexibly applicable to various kinds of electrode, each of which has different size and shape.

And it can be another object of the present invention to provide techniques which can be realized inexpensively.

According to one aspect of the present invention, a method of avoiding electrostatic discharge of an electronic device is provided. The method comprises the steps of: sticking an electroconductive sheet on the electronic device in order that all electrodes of the electronic device conduct electricity to each other though the electroconductive sheet; electrically connecting the electrodes with electrodes of another device; and peeling the electroconductive sheet from the electronic device.

According to another aspect of the present invention, a method of avoiding electrostatic discharge of an electronic device whose electrodes are connected with at least one filmed conductor is provided. The method comprises the steps of: peeling the film of the filmed conductor from at least one part of the filmed conductor to provide conductor electrodes; sticking an electroconductive sheet over the conductor electrodes in order that all of the conductor electrodes conduct electricity to each other though the electroconductive sheet; electrically connecting the conductor electrodes with electrodes of another device; and peeling the electroconductive sheet from the conductor electrodes.

According to another aspect of the present invention, a method of avoiding electrostatic discharge of an electronic device whose electrodes are connected with first terminal of a flexible printed circuit (FPC) is provided. The method comprises the steps of: peeling the film of the FPC from a part of the FPC to provide a exposed area where wires of the FPC are partly exposed; sticking an electroconductive sheet over the exposed area in order to make all of the wires become a single electric potential; inserting the first terminal into a connector so as to contact the first terminal with a second terminal of the connector; peeling the electroconductive sheet from the exposed area; and fixing the first terminal into the connector with the first and second terminals kept contacted with each other.

According to another aspect of the present invention, a flexible printed circuit (FPC) is provided. The FPC comprises: first electrodes for connecting with electrodes of an electronic device; second electrodes for connecting with electrodes of a connector which fixes the FPC; and an exposed area which is a part of the area on the FPC between the first and second electrodes and in which the film of the FPC is peeled off from the FPC. The wires on the FPC are electrically connected with each other when the electroconductive sheet is stuck on the exposed area.

According to the FPC mentioned above, the exposed area may be continuous to the second electrodes.

According to the FPC mentioned above, when the connector fixes the FPC at one end of the exposed area, which is the side of the second electrodes, the other side of the exposed area may be uncovered with the connector.

According to the FPC mentioned above, if the side of the second electrodes of the exposed area contacts the top of the electrodes of the connector, then the other side of the exposed area may project from the connector. And on the other hand, if the side of the second electrodes of the exposed area is inserted and the FPC is fixed on the connector, then the other side of the exposed area may be covered with the connector.

The FPC mentioned above may further comprise the electroconductive sheet stuck on the exposed area.

According to another aspect of the present invention, an electronic device is provided. The electronic device comprises the FPC mentioned above, and the first electrodes are connected with the electrodes of the electronic device.

For example, magnetoresistive devices are suitable for the electronic device mentioned above.

According to another aspect of the present invention, an electroconductive sheet is provided. The electroconductive sheet is to be stuck on an area of a FPC. Wires on the FPC is uncovered with the film of the FPC in the area, in order to electrically connect the wires with each other.

At least one side of the electroconductive sheet mentioned above may be to be folded.

### BRIEF DESCRIPTION OF THE DRAWING

FIG. 1 shows a top view for describing a magnetic head 40;

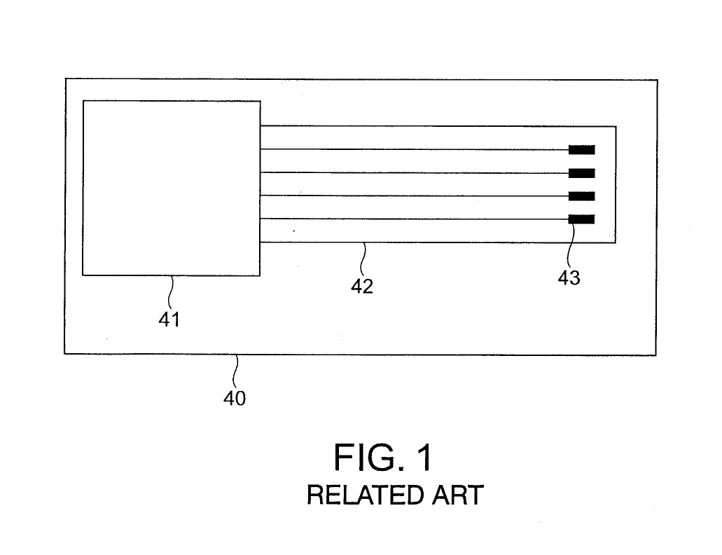

FIG. 2 shows top and side views for describing a conventional technique for avoiding electrostatic discharge of the magnetic head 40;

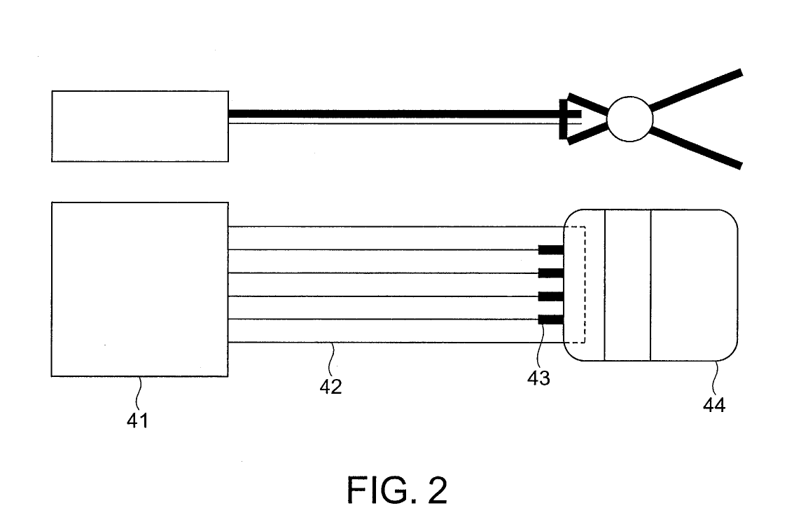

FIG. 3 shows a top view for describing the magnetic head 10, a first embodiment of the present invention;

FIG. 4 shows a top view of the electroconductive sheet 14;

FIG. 5 shows a section view for describing the structure of the conductive sheet 15.

FIG. 6 shows a side view for describing that the FPC 12 with the electroconductive sheet 14 is inserted into the connector 15, and a cross section view of the FPC 12 covered with the electroconductive sheet 14; and

FIG. 7 shows a side view for describing an second embodiment of the present invention.

### DESCRIPTION OF THE PREFERRED EMBODIMENTS

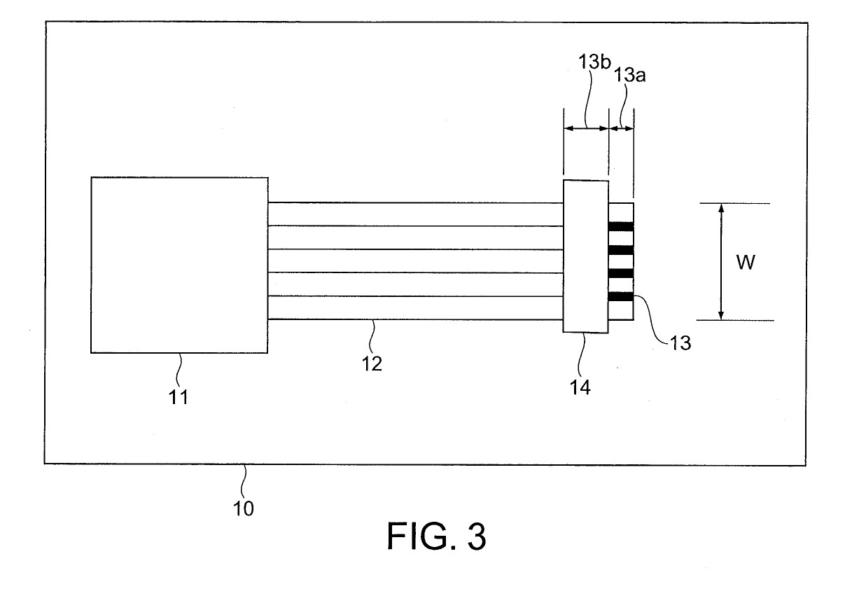

Description will be made about a magnetic head 10, a first embodiment of the present invention with reference to FIG. 3.

A magnetoresistive device 11 is connected via a flexible printed circuit (FPC) 12 to electrodes 13. The FPC 12 is covered with film, and on the other hand, the electrodes 13 are exposed from the film to conduct electricity. If the electrodes 13 are inserted into a connector (not shown), then the electrodes 13 are in contact with electrodes of the connector and the magnetoresistive device 11 is electrically connected with the connector.

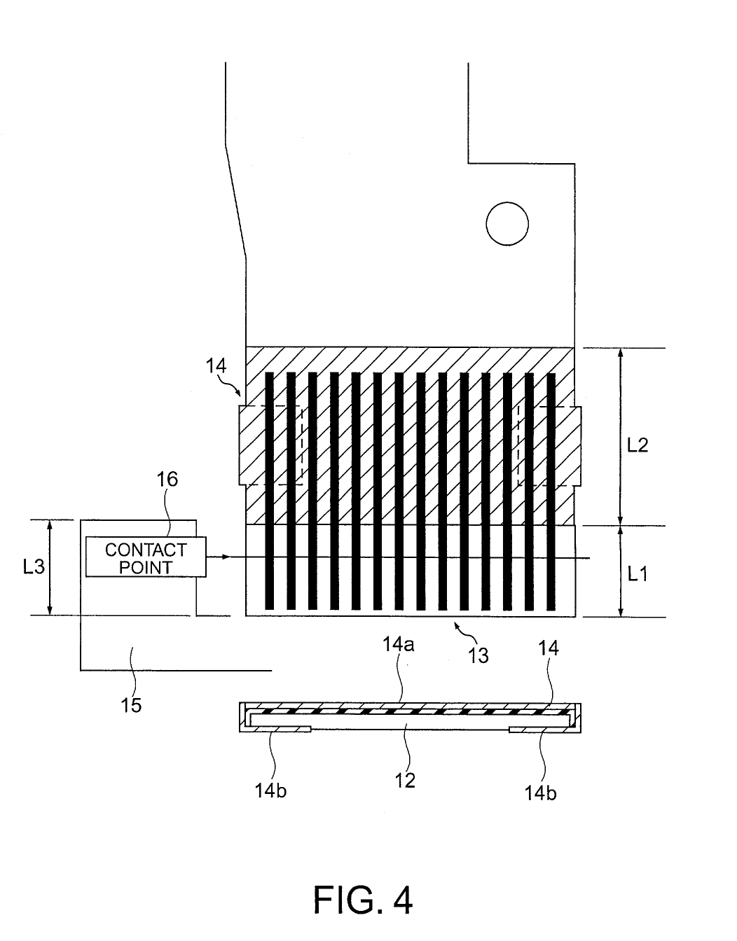

As shown in FIG. 4, each of the electrodes 13 comprises a first exposed portion 13a at an end portion of the FPC 12, which is shown at a lower end portion of the FPC in FIG. 4 and will therefore be referred to as a lower exposed member 13a. There is a second exposed portion 13b adjacent the lower exposed member 13a and is shown upper thereof in FIG. 4, which will therefore be referred to as an upper exposed member 13b. The lower exposed member 13a is a length L1 corresponding to the depth of a slit of the connector 15 for inserting the electrodes 13. The upper exposed member 13b is another length L2 corresponding to an area on which an electroconductive sheet 14 is to be stuck. Namely, each of electrodes 13 is exposed with a length of L1+L2 on the FPC 12. The electroconductive sheet 14 is stuck on the exposed member 13b in order that the electroconductive sheet 14 covers over the whole width of the FPC 12.

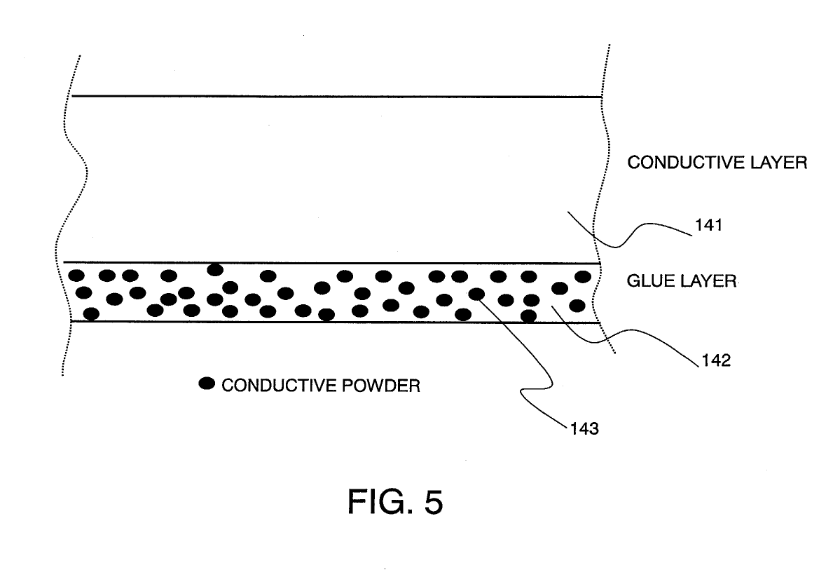

The following describes the structure of the electroconductive sheet 14 with reference to FIG. 5. Glue or adhesive mixed with powders of electroconductive material is spread or coated on the bottom of a sheet. The electroconductive sheet 14 is composed of an conductive layer 141 and a glue layer 142. The glue layer 142 includes conductive powders 143 dispersed therein.

The conductive layer 141 is a sheet of electroconductive material. In this embodiment, the conductive layer 141 is made of a copper foil. However, the conductive layer 141 may be made of not only metallic sheet, but also nonmetallic electroconductive material such as electroconductive plastic. The sheet may be made of not only foil, but also fabric such as a mesh woven from metallic wires.

The main ingredient of the glue layer 142 is an adhesive material for sticking the conductive layer 141 on the FPC 12. The electroconductive sheet 14 will be peeled off from the FPC 12 later. After the electroconductive sheet 14 is peeled off, it is desirable that the adhesive material is removed from the surface of the FPC 12. Such adhesive material is for example, acrylic adhesive, silicone adhesive or the like. Those adhesive materials are commercially available which are supplied by, for example, Nitto Denko, Sumitomo 3M, Daitac, Teraoka, which are Japanese companies, and others. The conductive powders 143 are powders of electroconductive material such as metallic powders, for example, cupper powder, aluminum powder, nickel powder or the like.

Alternatively, gel adhesive having ion-electroconductivity can be used for the adhesive layer, without use of the metallic powder.

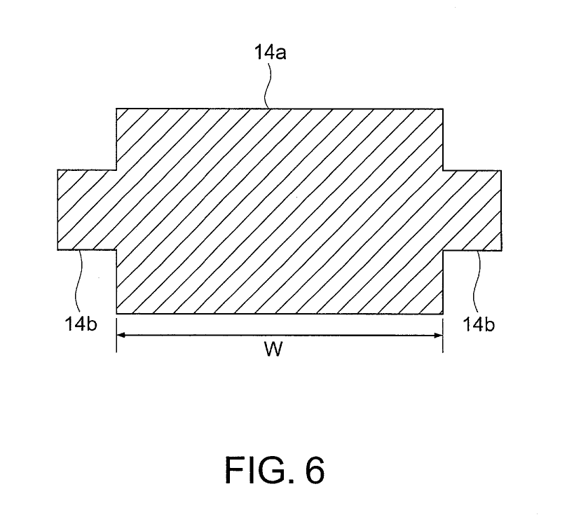

When the bottom side of the electroconductive sheet 14 is pressed on the upper exposed member 13b, the electroconductive sheet 14 is electrically connected with the upper exposed member 13b via the conductive powders. As a result, the wires on the FPC 12 are electrically connected with each other via the electroconductive sheet 14. The electroconductive sheet 14 has the shape shown in FIG. 6.

As shown in FIG. 6, the electroconductive sheet 14 is composed of a center member or portion 14a and two convex members or two protruding portions 14b. The center member 14a is a rectangle. One of the convex members 14b laterally projects from the center of one side of the center member 14a. The other convex member 14b also laterally projects from the center of the opposite side of the center member 14a. The width W of the center member 14a corresponds to the width W of the FPC 12. After the electroconductive sheet 14 is stuck on the upper exposed member 13b, each of the convex members 14b is folded around the upper exposed member 13b.

Description will be made about the process of connecting the magnetic head 10 with the connector 15.

First, the electroconductive sheet 14 is stuck on the upper exposed member 13b. As a result, the electrodes 13 are electrically short-circuited to each other or closed and consequently the magnetoresistive device 11 is protected from electrostatic discharge.

Next, as shown in FIG. 4, the electrodes 13 on which the electroconductive sheet 14 is stuck are inserted into the slit of the connector 15 to fix the FPC 12 on the connector 15. The electrodes 13 become in contact with contact points 16 while the magnetoresistive device 11 is kept electrically closed.

Finally, the electroconductive sheet 14 is peeled from the upper exposed member 13b. It can make the peeling-off of the sheet 14 easier to pull the convex member 14b turned over on the back of the upper exposed member 13b.

When the electrodes 13 is fixed on the connector 15, the lower exposed member 13a is accommodated in the slit of the connector, and on the other hand, the upper exposed member 13b and the electroconductive sheet 14 stuck on the upper exposed member 13b jut out from the slit. Namely, the depth L3 of the slit of the connector 15 is nearly equal to the length L1, as shown in FIG. 4.

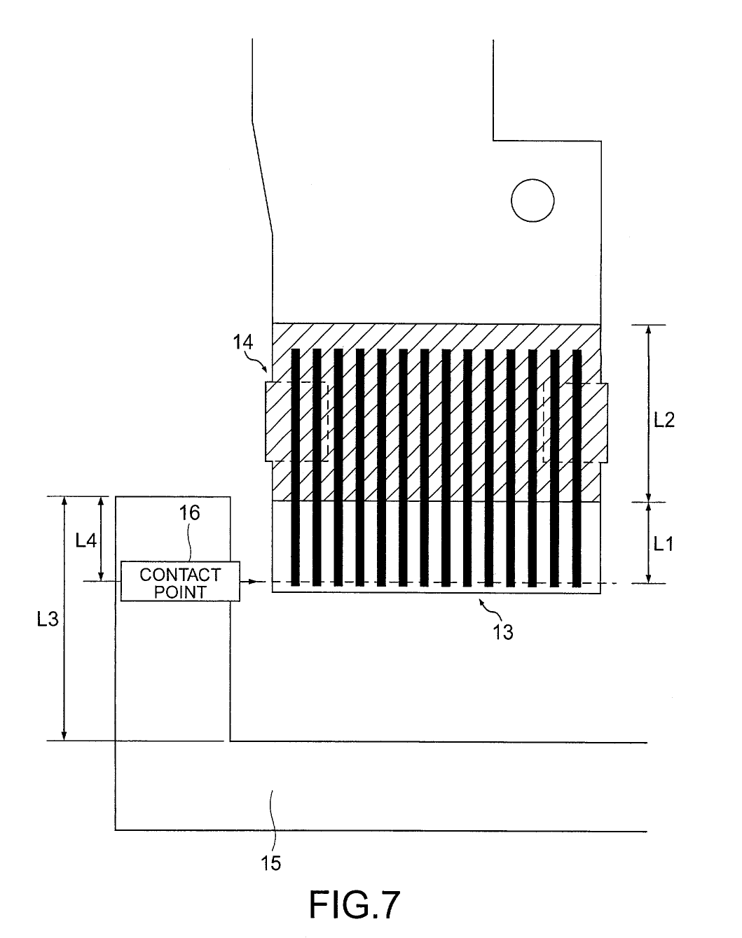

Description will be made about a second embodiment of the present invention with reference to FIG. 7.

According to the first embodiment, the length L1 of the lower exposed member 13a corresponds to the depth L3 of the slit of the connector 15. On the other hand, according to the second embodiment, the length L1 of the lower exposed member 13a corresponds to a size or depth L4 between the top of the slit and the contact points 16, as shown in FIG. 7. Namely, the length L1 is nearly equal to the depth L4. The sum of the lengths L1 and L2 corresponds to the depth L3 of the slit of the connector 15. The sum of the lengths L1 and L2 is nearly equal to the depth L3. It is noted that when each of the electrodes 13 is fixed on the connector 15: according to the first embodiment, the upper exposed member 13b juts out from the top of the connector 15; and on the other hand, according to the second embodiment, the upper exposed member 13b is accommodated in the slit of the connector 15.

Further, there is a difference in the process of connecting the magnetic head 10 with the connector 15. The difference will appear in the following description.

First, the electroconductive sheet 14 is stuck on the upper exposed member 13b as shown in FIG. 3. The electrodes 13 become electrically closed and the magnetoresistive device 11 is protected from electrostatic discharge.

Next, while the electroconductive sheet 14 is kept stuck on the upper exposed member 13b, the electrodes 13 are inserted into the connector 15 until the ends of the electrodes 13 come into contact with the contact points 16. At this step, each of the electrodes 13 is partly inserted into the connector 15. The magnetoresistive device 11 is kept electrically closed while the electrodes 13 is in contact with the contact points 16.

After that, the electroconductive sheet 14 is peeled from the upper exposed member 13b. It can make the peeling-off of the sheet easier to pull the convex member 14b turned over on the back of the upper exposed member 13b.

Finally, the electrodes 13 are fully inserted into the connector 15 to fix the electrodes 13 to the connector 15. At this step, both of the upper and lower exposed members 13a and 13b are completely accommodated in the slit of the connector 15.

For example, the present invention will have the following results.

Electrodes of an electronic device are connected with a connector and then an electroconductive sheet stuck on the electrodes is peeled off. Consequently, no defenseless time period against electrostatic discharge of the electronic device occurs.

Further, after inserting electrodes of an electronic device into a connector, it is required only to peel an electroconductive sheet from the electrodes. The process of peeling off the sheet requires relatively small working space. Therefore, the electronic device can be easily installed.

Further, it is easy to provide flexible electroconductive sheets, which are available for electrodes on not only a single plane, but also a curved surface, plural planes and plural curved surfaces. It is also easy to cut an electroconductive sheet into various shapes each of which is suitable for a different type of electrodes of electronic devices. Therefore, one electroconductive sheet is applicable to various kinds of electronic devices. On the other hand, conventional technique with a metallic clip is applicable only to a single plane, and is restricted applicable electronic devices under the size and shape of a metallic clip.

And further, electroconductive sheets easily admit of mass production. Therefore, the present invention can be realized inexpensively.

While this invention has thus far been described in conjunction with several embodiments thereof, it will be readily possible for those skilled in the art to put this invention into various other manners.

For example, electronic devices applicable to the present invention are not only magnetic heads and magnetoresistive devices, but also other electronic devices sensitive to electrostatic discharge. Such electronic devices are, for example, integrated circuits.

Further, in the description mentioned above, the electroconductive sheet mentioned above is made of copper foil. However, electroconductive sheets may be other metallic foil or non-metallic foil. However, electroconductive sheets of the present invention may be made of other metal or non-metallic conductive material, such as conductive plastic. Sheets of the electroconductive sheets may be formed as not only foil, but also fabric.

Further, though bottom sides of electroconductive sheets require conductivity of electricity, the top sides do not necessarily require the conductivity. Therefore, a top side of an electroconductive sheet may be insulator while the bottom side is conductor.

And further, the electroconductive sheet mentioned above is stuck on a FPC. However, the electroconductive sheet of the present invention is applicable to various kinds of filmed wires.

What is claimed is:

1. A method of avoiding electrostatic discharge of an electronic device, comprising the steps of:
sticking an electroconductive sheet on the electronic device in order that all electrodes of the electronic device conduct electricity to each other though the electroconductive sheet;
electrically connecting the electrodes with electrodes of another device; and
peeling the electroconductive sheet from the electronic device.

2. A method of avoiding electrostatic discharge of an electronic device whose electrodes are connected with at least one filmed conductor, the method comprising the steps of:
peeling the film of the filmed conductor from at least one part of the filmed conductor to provide conductor electrodes;
sticking an electroconductive sheet over the conductor electrodes in order that all of the conductor electrodes conduct electricity to each other though the electroconductive sheet;
electrically connecting the conductor electrodes with electrodes of another device; and
peeling the electroconductive sheet from the conductor electrodes.

3. A method of avoiding electrostatic discharge of an electronic device whose electrodes are connected with first terminal of a flexible printed circuit (FPC), the method comprising the steps of:
peeling the film of the FPC from a part of the FPC to provide a exposed area where each of wires of the FPC is partly exposed;
sticking an electroconductive sheet over the exposed area in order to make all of the wires become a single electric potential;
inserting the first terminal into a connector so as to contact the first terminal with a second terminal of the connector;
peeling the electroconductive sheet from the exposed area; and
fixing the first terminal into the connector with the first and second terminals kept contacted with each other.

4. A flexible printed circuit (FPC) comprising:
first electrodes for connecting with electrodes of an electronic device;
second electrodes for connecting with electrodes of a connector which fixes the FPC; and
an exposed area which is a part of the area on the FPC between the first and second electrodes and in which the film of the FPC is peeled off from the FPC,
wherein the wires on the FPC are electrically connected with each other when the electroconductive sheet is stuck on the exposed area.

5. The FPC claimed in claim 4, wherein the exposed area is continuous to the second electrodes.

6. The FPC claimed in claim 5, wherein when the connector fixes the FPC at one end of the exposed area, which is the side of the second electrodes, the other side of the exposed area is uncovered with the connector.

7. The FPC claimed in claim 5, wherein:
if the side of the second electrodes of the exposed area contacts the top of the electrodes of the connector, then the other side of the exposed area projects from the connector; and
if the side of the second electrodes of the exposed area is inserted and the FPC is fixed on the connector, then the other side of the exposed area is covered with the connector.

8. The FPC claimed in claim 4, further comprising the electroconductive sheet stuck on the exposed area.

9. An electronic device comprising the FPC claimed in claim 4, wherein the first electrodes are connected with the electrodes of the electronic device.

10. The magnetoresistive device claimed in claim 9 as the electronic device.

11. An electroconductive sheet for being stuck on an area of a FPC, in which wires on the FPC is uncovered with the film of the FPC, in order to electrically connect the wires with each other.

12. The electroconductive sheet claimed in claim 11, wherein at least one side of the electroconductive sheet is to be folded.

13. The electroconductive sheet claimed in claim 11, comprising:
a conductive layer made of electroconductive material;
a glue layer made of adhesive material coated on the conductive layer; and
conductive powders made of electroconductive material and dispersed in the glue layer.

14. The electroconductive sheet claimed in claim 13, wherein the conductive layer is made of metal.

15. The electroconductive sheet claimed in claim 13, wherein the conductive layer is made of non-metal electroconductive material.

16. The electroconductive sheet claimed in claim 13, wherein the conductive layer is made of metallic foil.

17. The electroconductive sheet claimed in claim 13, wherein the conductive layer is made of electroconductive fabric.

18. The electroconductive sheet claimed in claim 13, wherein the adhesive material is at least one of acrylic adhesive and silicone adhesive.

19. The electroconductive sheet claimed in claim 13, wherein the conductive powders are metallic powders.

20. The electroconductive sheet claimed in claim 11, comprising:
a conductive layer made of electroconductive material; and
a glue layer coated on the conductive layer; said glue layer being made of gel adhesive having ion-electroconductivity.
